(19) United States
(12) Patent Application Publication
(10) Pub. No.: US 2003/0082884 A1
(43) Pub. Date: May 1, 2003

(54) Method of forming low-leakage dielectric layer

(75) Inventors: Johnathan Faltermeier, Lagrange, NY (US); Keitaro Imai, Yokohama (JP); Rajarao Jammy, Wappingers Falls, NY (US); Takanori Tsuda, Oita City (JP)

Correspondence Address: Jack P. Friedman, SCHMEISER, OLSEN & WATTS LLP, 3 Lear Jet Lane, Suite 201, Latham, NY, 12110, US

(73) Assignee: International Business Machine Corporation and Kabushiki Kaisha Toshiba, Armonk, NY

(21) Appl. No.: 09/999,824

(22) Filed: Oct. 26, 2001

(51) Int. Cl. H01L 21/8242; B05D 5/00; H01L 21/20

(52) U.S. Cl. 438/387; 438/244

(57) ABSTRACT

Two new processes are disclosed for forming a high quality dielectric layer. A first process includes a re-nitridation step following the oxidation of an SiN film in the formation of a dielectric layer. A second process includes a sequential nitridation step to form a SiN film in the formation of a dielectric layer. In a particular embodiment of the second process, sequential ammonia annealing at elevated temperatures is used to bake sequentially deposited thin nitride layers. By using these methods, dielectric films with higher capacitance and lower leakage current have been obtained. The methods described herein have been applied to a deep trench capacitor array, but is equally applicable for other device dielectrics including, but not limited to, stacked capacitor DRAMs.

### BACKGROUND OF THE INVENTION

1. Technical Field

This invention generally relates to fabrication of integrated circuit devices, and more specifically relates to fabrication of on-chip devices having improved dielectric films.

2. Background Art

In the semiconductor industry, dielectric films, such as silicon dioxide films (SiO₂, also called oxide films, or Si₃N₄) are used in a variety of applications including, but not limited to, gate dielectrics as spacers and liners, transistors, and other integrated circuit devices. In recent years, the need to remain cost and performance competitive in the production of semiconductor devices has caused continually increasing device density in integrated circuits. To facilitate the increase in device density, new technologies are constantly needed to allow the feature size of these semiconductor devices to be reduced without loss of device performance. This need has further increased the importance of the ability to provide extremely thin, reliable, low-defect and manufacturable dielectric films.

The push for ever increasing device densities is particularly strong in Dynamic Random Access Memory (DRAM) markets. One particular area of concern in DRAM design is the storage capacitor used to store each memory cell. The density of DRAM designs is to a great extent limited to by the feature size of the storage capacitor.

A charge stored in a storage capacitor is subject to current leakage and, therefore, DRAM must be refreshed periodically. The time allowed between refresh without excess charge leakage is the “data retention time”, which is determined by the amount of charge stored at the beginning of the storage cycle and the amount of leakage current through different kinds of leakage mechanisms. Many efforts are expended to minimize the leakage mechanisms so as to extend the time allowed between refresh cycles.

Several methods have been used to facilitate the shrinkage of the capacitor feature size while maintaining sufficient capacitance. For example, stacked capacitors have been located above the transfer devices. Unfortunately, this approach presents difficulties with topography and with connecting the capacitors.

Another approach has been the use of trench capacitors as storage capacitors. Trench capacitors extend the storage node into the substrate to increase the capacitance without increasing the area used on the substrate. The trench capacitor design conventionally uses a highly conductive single crystal silicon substrate as the counter electrode, and a highly conductive polycrystalline silicon in a deep trench as the storage electrode of the capacitor. By extending the capacitor in the vertical dimension, trench capacitors allow the capacitor feature size to be decreased without decreasing the resulting capacitance. Capacitance for a trench capacitor is described by the following equation:

$$C = K \times \frac{{A}_{trench}}{{T}_{film}}$$

Where C is capacitance, K is the dielectric constant of the node dielectric layer, A_{trench} is the sidewall area of the trench, and T_{film} is the thickness of the node dielectric film. As described by the previous equation, the capacitance of a trench capacitor is linearly dependent upon the sidewall area of the trench and the dielectric constant of the node dielectric layer, and inversely dependent upon the thickness of the dielectric film.

Traditionally, as the trench area decreases, the capacitance has been maintained by decreasing the thickness of the dielectric film. For example, Si3N4 node dielectric films have been aggressively scaled in thickness for each DRAM generation to maintain the requisite capacitance. As the thickness decreases, however, the leakage current through the dielectric film becomes higher and it degrades the charge retention capability of the memory storage cell. The leakage currents across the node dielectric must be low enough that the stored charge, which delineates either a “1” or a “0” bit state, remains long enough to be detected at a later time. The tunneling currents are exponentially dependent upon the thickness of the node dielectric layer and the barrier height between the electrode material and the node dielectric layer. Thinning the node dielectric layer causes an exponential increase in leakage current, placing a limit on how much the node dielectric can be thinned.

Although the SiN is very thin, it is still above the direct tunneling regime. Thus, the nitride film quality needs to be improved in order to suppress the leakage current. Oxidation of the SiN film has been used to reduce leakage current mainly because it is conventionally believed to reduce defects and the oxide on the SiN works as a leakage barrier as well due to its higher band gap. However, since SiO2 has a lower dielectric constant than SiN, the effective dielectric constant of the NO film is also lower. Additionally, as SiN thickness decreases, oxide punch-through during the oxidation step becomes an issue, which degrades the film. Since a nitride film is conventionally formed by low pressure chemical vapor deposition (LPCVD) at a relatively low temperature of 700 C., defects such as Si dangling bonds and/or hydrogen incorporation, or even pinholes are likely and result in high leakage current. Although oxidation of the SiN film has been used to suppress such defects, there are drawbacks with oxidation as previously mentioned.

It is customary to measure the thickness of a gate insulator in terms of an equivalent silicon oxide thickness (EOT). The EOT of the dielectric is simply a measure of its capacitance in relation to SiO2. When silicon oxide is used as the dielectric of a capacitor, its EOT is close to its physical thickness. A fundamental parameter that limits the physical thickness of a gate insulator and, consequently, its EOT, is the leakage current through a thin dielectric. High-performance FETs in logic circuits require a gate leakage current of less than 1-10 A/cm². Accordingly, gate insulators are selected, in-part, on the basis of their EOT and a leakage current of less than 1-10 A/cm². A quality factor for a gate insulator includes long-term reliability parameters, interface trap density, and fixed mobile charge.

For a typical DRAM capacitor, the leakage current should be below 10⁻⁷ A/cm² in order to retain the stored charge for several milliseconds. In addition, capacitors are not sensitive to the interface charge density. This allows for the use of a wide variety of dielectric materials in a capacitor which are not suitable for gate insulators due to the density of interfacial traps. Accordingly, the present disclosure relating to on-chip capacitors is different from the art of thin gate insulators due to the different requirement on the allowed leakage current: I_{leakage}<10⁻⁴ A/cm².

Thus, there is a continuous need for improved dielectric films, and improved methods of on-chip dielectric fabrication, particularly among on-chip capacitors to maintain capacitance values despite continued reductions in capacitor area and minimum node dielectric layer thickness limits.

### DISCLOSURE OF THE INVENTION

The present invention provides an improved dielectric film for on-chip devices. In particular, the present invention involves two new processes to address the problems presently faced in the art with forming dielectric films. The first process comprises employing a re-nitridation step following the oxidation of a SiN film step in the formation of a dielectric film. The second process comprises employing a sequentially cycled nitridation process, such as ammonia annealing at a higher temperature, for an improved chemical vapor deposition (CVD) SiN deposition process. The improved dielectric film resulting from each of these processes increases the capacity of an on-chip capacitor or reduces the leakage current when compared to films grown or deposited by conventional techniques.

The foregoing and other features and advantages of the present invention will be apparent from the following more particular description of embodiments of the invention, as illustrated in the accompanying drawings.

### BRIEF DESCRIPTION OF THE DRAWINGS

FIGS. 1 and 2 are cross-sectional views of a deep trench capacitor at various stages of the fabrication process, the deep trench capacitor having a node dielectric layer configured according to an embodiment of the present invention;

FIG. 3 illustrates a device with deep trench capacitor having a node dielectric layer configured according to an embodiment of the present invention;

FIG. 4 is a graph diagram of capacitance versus voltage for each of a first capacitor fabricated by a conventional process (POR) and a second capacitor fabricated to have a dielectric layer configured according to an embodiment of a first process of the present invention;

FIG. 5 is a graph diagram of current versus voltage for a first capacitor fabricated by a conventional process (POR) and a second capacitor fabricated to have a dielectric layer formed by a process involving renitridation of the oxide on the SiN film according to an embodiment of a first process of the present invention;

FIG. 6 is a graph diagram of an FTIR spectra for capacitors fabricated according to each of a plurality of embodiments of the present invention;

FIG. 7 is a graph diagram of current versus voltage for a capacitor fabricated by a conventional process (POR), and two capacitors each fabricated to have a SiN single film dielectric layer formed by sequential ammonia annealing according to an embodiment of a second process of the present invention; and

FIG. 8 is a graph diagram of capacitance versus voltage for a capacitor fabricated by a conventional process (POR), and two capacitors each fabricated to have a SiN single film dielectric layer formed by sequential ammonia annealing according to an embodiment of a second process of the present invention.

### DETAILED DESCRIPTION OF EMBODIMENTS OF THE INVENTION

As discussed above, embodiments of the present invention described herein relate to the formation of improved dielectric films for on-chip devices, and the use of an improved node dielectric layer having an increased dielectric constant to increase capacitance. While the figures provided herein relate specifically to a node dielectric layer and fabrication method for an on-chip trench capacitor which increases its dielectric constant, it will be understood by those of ordinary skill in the art that the principles of the present invention may be applied to improve a variety of dielectric film applications. Additionally, it will be clear to those of ordinary skill in the art that the methods described herein also apply to other on-chip capacitors such as, for example, stacked capacitors and capacitors used in radio frequency (RF) circuits.

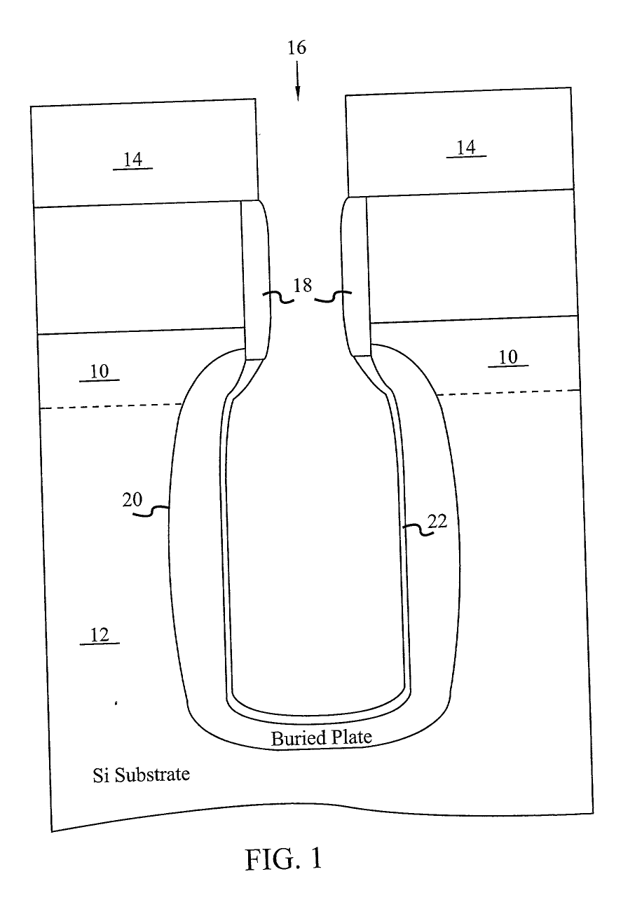

Although the present invention may be readily adapted to a variety of methods of fabricating an on-chip capacitor, with reference to FIG. 1, the following is one example of a method of fabrication. It should be understood that the invention is not limited to the specific structures illustrated in the drawings or to the specific steps detailed herein. While the drawings illustrate a bottle-shaped trench, the invention may be practiced using capacitors of other shapes and employing alternative void-forming techniques. It should also be understood that the invention is not limited to use of any specific dopant type provided that the dopant types selected for the various components are consistent with the intended electrical operation of the device.

FIG. 1 is a diagram of a bottle-shaped deep trench capacitor at a stage during the fabrication of the trench capacitor according to the embodiments of the present invention. As will be clear to one of ordinary skill in the art from the disclosure herein, the present invention may be used to improve the node dielectric layer of capacitors in conjunction with a variety of fabrication processes. In the embodiments discussed, the methods of the present invention begin with traditional capacitor formation techniques. The embodiments of the methods described herein each begin with forming a lightly doped region 10 in a semiconductor substrate 12. Semiconductor substrate 12 may be formed from any conventional semiconducting material, including, but not limited to Si, Ge and SiGe. For the exemplary purposes of this disclosure, the semiconductor substrate 12 of the following examples is a silicon substrate 12.

The pad dielectric layer 14 (which typically includes a silicon nitride layer) may be formed on the silicon substrate 12. A trench pattern 16 with a narrow upper regions may be etched into the pad dielectric layers 16, and deep trenches with broad lower regions may be etched into the silicon substrate 12. The methods described here are not limited, however, to bottle-shaped capacitor structures. An oxide collar 18 may be formed in the narrow upper region of the trench by local oxidation of silicon (LOCOS) or one of the many available techniques. At the broad lower region of the trench, a buried plate 20 may be formed as an out-diffusion from the trench 16, with the oxide collar 18 serving as a mask. These steps may be accomplished using any of the available techniques. In some instances, it may also be desirable to form a thin oxide layer (not shown) between semiconductor substrate 12 and pad dielectric 14.

The initial bottle-shaped structure shown in FIG. 1 may be fabricated using conventional techniques that are well known to those of ordinary skill in the art. For example, the bottle-shaped structure may be fabricated using the processes disclosed in U.S. Pat. Nos. 4,649,625 to Lu, 5,658,816 to Rajeevakumar, 5,692,281 to Rajeevakumar, and 6,194,755 B1 to Gambino et al., the disclosures of which are hereby incorporated herein by reference. The buried plate may be formed by any conventional technique of diffusing the appropriate conductivity type dopant through the trench wall. See, for example, the technique disclosed in U.S. Pat. No. 5,395,786 to Hsu et al, the disclosure of which is hereby incorporated herein by reference.

A node dielectric layer 22 may be formed over the buried plate 20 in the trench. In a conventional process, referred to herein as a POR, a node dielectric layer is formed according to the following process: First, exposing the trench to ammonia gas to nitride the Si sidewalls of the trench; Second, performing a LPCVD of SiN to create a stoichiometric, high quality SiN layer (dielectric constant of approximately 7.5) over the nitrided sidewalls; and Third, performing a wet oxide process in a furnace which exposes the wafer to water vapor at a high temperature to re-oxidize the top layer of SiN. The third step, which re-oxidizes the top layer of SiN in a furnace, converts approximately 5-20 Å of SiN to SiO2 of medium quality. The SiO2 layer acts as an leakage barrier to stop leakage of tunneling electrons. The SiO2, however, reduces the effectiveness of the overall dielectric because it has a lower dielectric constant.

In accordance with a first process of the present invention, the node dielectric layer is formed on a semiconductor surface by nitriding the Si sidewall of the trench by exposure to ammonia gas (e.g. NH3 bake at 800-1100 C. for 10-30 min, or particularly 950 C. for 10-30 min) or other method known in the art. Then, an LPCVD process is used to deposit between 5-50 Å of SiN using a nitrogen containing gas and a silicon containing gas (e.g. ammonia and SiH₂Cl₂). Next, the nitrided Si sidewall is oxidized by wet oxide in a furnace, free radical enhanced rapid thermal oxidation (FRE RTO), or other oxidation method known in the art, to convert a portion of the SiN in the sidewall to SiO2. FRE RTO may be performed by flowing O2 and H2 into a single wafer tool which is operating at elevated temperatures (e.g. 900-1100 C.). The O2 and H2 react on the hot wafer to create H2O and atomic oxygen used to oxidize the nitrided Si sidewall. Depending upon the desired thickness of the oxidized portion of the nitrided Si sidewall, reaction times may vary 2-300 sec and reaction temperatures may vary between 600-1200 C. By generating the SiO2 by FRE RTO rather than by wet oxide in a furnace, a higher quality film is generated. The quality of the film relates to the amount of leakage through the film, which is related to the bandgap of the film, which is related to stoichiometry. Lower leakage through the film is evidence of a higher purity film.

Following the oxidation step, the oxidized sidewall film on the SiN is converted into an oxynitride or a nitride by any nitridation process known in the art, such as may be performed in an ammonia or nitrogen at a temperature between 25 C. and 1150 C. or above (1000 C. in a particular embodiment). While the nitridation may be accomplished by any nitridation process, in a particular embodiment of the invention, the sidewall is nitrided by at least one of rapid thermal nitridation (RTN), remote plasma nitridation (RPN), and decoupled plasma nitridation (DPN). The RPN and DPN expose the trench to atomic nitrogen, a plasma process which breaks apart the N atoms and makes them very reactive. Conventionally RPN processes are performed at temperatures between 500-900 C., and in one embodiment at 550 C., for 30-240 seconds depending upon the desired thickness of the nitrided portion. The RPN approach is particularly suitable for applications where low thermal budgets are necessary such as in stacked capacitor structures using conventional NO dielectrics. DPN processes are conventionally performed at temperatures between 60-300 C., and in one embodiment around 100 C., for 30-240 seconds depending upon the desired thickness of the nitrided portion. One of ordinary skill in the art will readily be able to determine an appropriate temperature and duration for a desired thickness. The RTN process uses ammonia gas to nitride the oxidized layer. RTN processes are conventionally performed at elevated temperatures (850-1150 C.) for between 5-60 seconds, though longer times are contemplated. Furthermore, although it is not limited to a single wafer tool, this process may be performed using a single wafer tool. The existence of SiO2 is desirable to reduce electron tunneling. However, the SiO2 reduces the total dielectric effectiveness of the node dielectric because of its lower dielectric constant. By nitriding the oxidized layer, the stoiciometry of the node dielectric layer and the dielectric constant of the layer are improved, improving node reliability. Thus, according to embodiments of the first process of the invention, a dielectric layer may be formed by: 1) nitriding the Si sidewall; 2) depositing a silicon nitride layer; 3) oxidizing the nitride layer; and 4) nitriding a portion of the oxidized sidewall.

According to a second process of the present invention, the node dielectric layer is formed on a semiconductor surface by nitriding the Si sidewall of the trench through sequential nitridation process. Through the sequential nitridation process, the Si sidewall is nitrided in small, high quality portions which results overall in a higher quality dielectric layer than through conventional nitriding of the Si sidewall. By forming the nitridation layer on the Si sidewall in small steps, the defects in the bulk SiN film may be suppressed. In one embodiment of the second process, the sidewall is nitrided through sequential ammonia annealing by first, depositing a thin layer of nitride on the Si sidewall (5 Å in a particular embodiment) through a conventional nitride deposition process, and then baking that nitride layer at an elevated temperature in a nitridizing ambient, such as by soaking the layer in ammonia or nitrogen at a temperature between 25 C. and 1150 C. or above. A second thin layer of nitride is then deposited on the nitrided sidewall (again 5 Å in a particular embodiment), and the sidewall is again baked at an elevated temperature or nitrided in a nitrogen-containing plasma. This process may be repeated several times until the desired thickness is achieved. Larger or smaller thickness deposition steps may be applied depending upon the needs of a particular process. By depositing thicker layers, the overall process time is reduced, but there is a trade-off with layer quality. The inventors of the present invention found that sequentially depositing layers of approximately 5 Å was sufficient for the purposes of the experiments described herein.

This sequential process of ammonia annealing the sidewall slowly builds up sequential layers of nitride which boosts the capacitance through a more ideal dielectric constant. Additionally, due to the lower leakage resulting from the higher quality nitride layer, in some embodiments of the invention, oxidation of the nitrided Si sidewall may not be necessary. In another particular embodiment of the second process of the invention, thin layers of nitride are sequentially deposited and re-nitrided instead of being exposed to ammonia, by any nitridation method known in the art such as through RTN, RPN or DPN. Thus, according to embodiments of the second process of the invention, a dielectric layer may be formed by: 1) sequentially nitriding the Si sidewall; and 2) optionally oxidizing the nitrided sidewall of the trench.

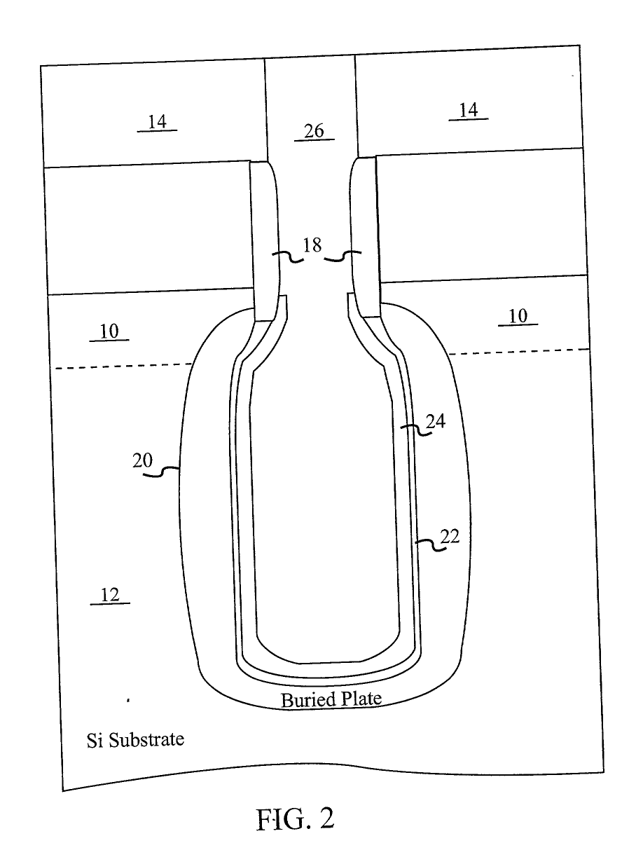

Referring now to FIG. 2, once the node dielectric layer 22 is formed according to an embodiment of the present invention, the remainder of the capacitor is formed according to conventional capacitor forming techniques such as those described in the patent discloses previously incorporated herein by reference. Conventionally, the trench 16 is layered with a polysilicon or doped polysilicon layer 24 in a suitable manner such as by LPCVD using SiH4 and AsH3 as reactants at a temperature that will not disturb the thermal budget (e.g., preferably between 500 and 600° C.).

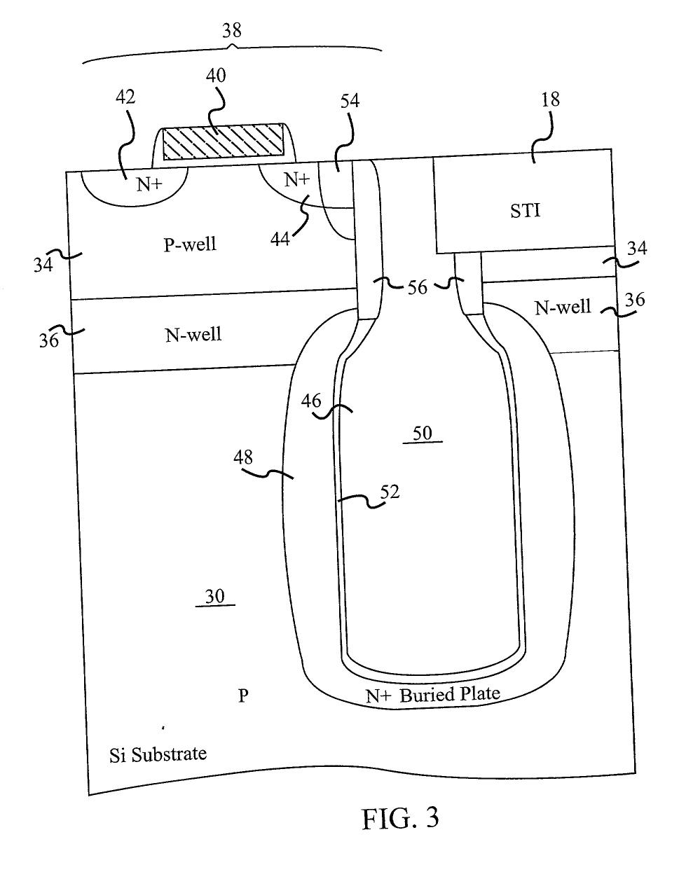

The trench capacitor of the above described invention may be further refined by the use of a substrate plate trench design. Referring to FIG. 3, there is shown a schematic cross-sectional view of the basic buried plate trench DRAM cell 30. The cell includes a substrate 32 of P type semiconductor. A P-well 34 is formed above an N-well 36. At the upper surface of the P-well 34 a transfer device 38 is formed that includes a control gate 40 that is responsive to a word access line of the DRAM array support circuits (not shown). The transfer device 38 couples data between bit line diffused N⁺ region 42 and diffused N⁺ region 44 through the channel region formed in P-well 34. A deep trench 46 is formed into the substrate 30. Surrounding the deep trench 46 is formed a buried plate 48 that serves as the capacitor counter electrode, and is connected to the buried plates of other cells through N-well 36. Inside deep trench 46, a capacitor storage node may be formed comprising an N⁺ type polysilicon electrode 50 isolated from substrate 30 by a thin dielectric layer 52 formed according to an embodiment of the present invention. N⁺ region 44 and the polysilicon storage node 50 are connected by a buried strap 54. At the top of the storage trench 46 is a thick isolating collar 56 which serves to prevent vertical leakage. STI region 58 serves to isolate this cell 30 from others in the array. It is also true for other structures such as a vertical gate structure where the gate dielectric is formed on the sidewall trench above the collar region.

Accordingly, it will be clear to those of ordinary skill in the art that the present invention provides a method of forming an improved dielectric film. In one process of the present invention, the dielectric film is formed by nitriding a Si surface, oxidizing the surface and then re-nitriding that surface. In another process of the present invention, the dielectric film is formed by sequentially nitriding the Si surface and then optionally oxidizing that surface. The surface may further be re-nitrided if desired in a particular application. Particular embodiments of the invention described involve capacitor dielectrics. The higher performance of the capacitor means a high value of capacitance (lower value of EOT) at the same leakage current. Alternatively, this may be explained as a lower leakage value at the same EOT value.

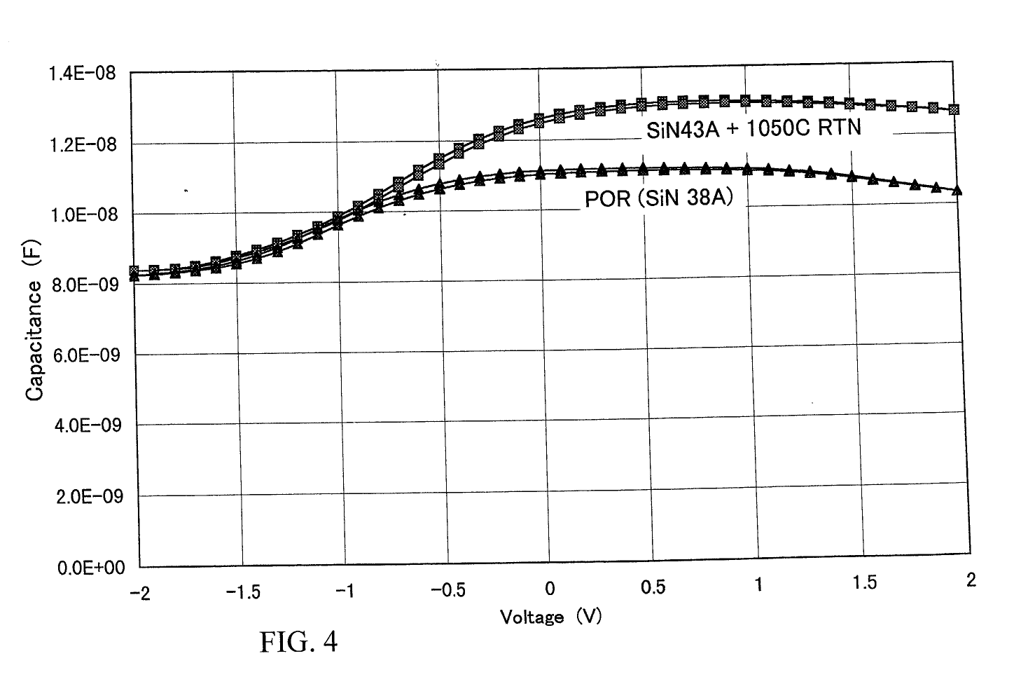

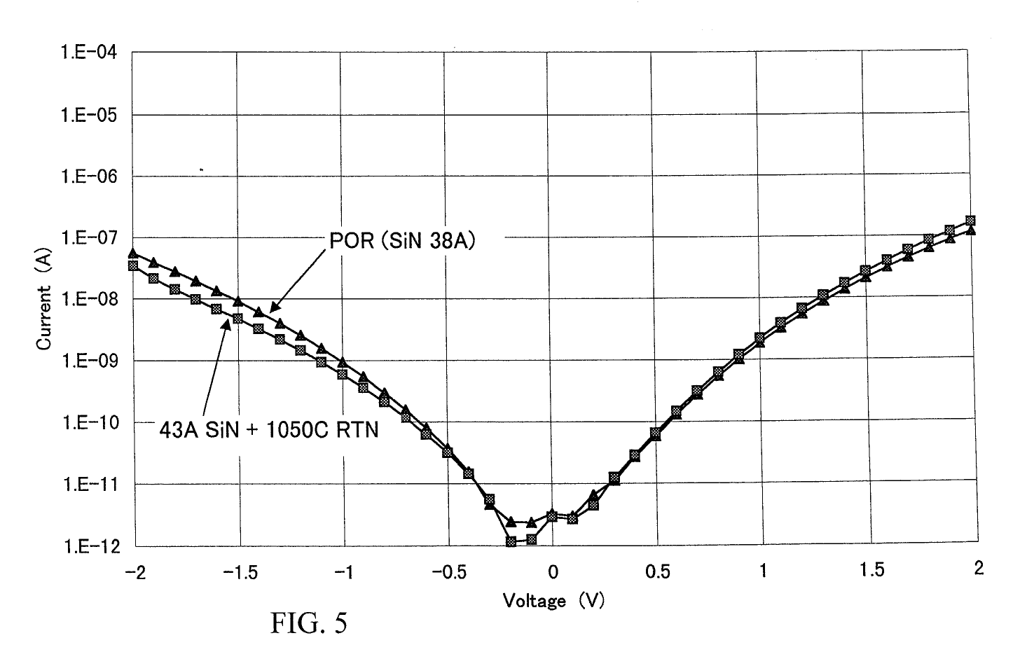

Experiments were conducted to determine the performance of two 256 K trench array capacitors, one having a dielectric film fabricated according to an embodiment of the re-nitridation method of the present invention, and another having a dielectric film fabricated according to a conventional method (POR). FIGS. 4 and 5, respectively, include chart diagrams of capacitance vs. voltage and current vs. voltage for 256 K trench array capacitors to compare conventional NO dielectrics and dielectrics using a re-nitridation technique according to an embodiment of the first process of the invention. The initial SiN thickness of the samples chosen for this experiment were 3.8 nm in the conventional POR case and 4.3 nm for the re-nitridation case. These wafers were oxidized to 250 Å EOT on Si for the POR case and 300 Å EOT on Si for the renitridation case. The comparison was purposefully made on samples with different nitride and oxide thicknesses to make a more stringent comparison. Re-nitridation was then performed in ammonia at 1050 C. and 500 Torr for 30 sec by RTN. This results in the nitridation of the oxidized portion of the node nitride, giving the dielectric layer an overall higher dielectric constant and an increase in capacitance.

As is indicated by the capacitance to voltage chart of FIG. 4 and the current to voltage chart of FIG. 5, the capacitance is approximately 20% increased by using the nitridation process of the present invention without a big penalty in the leakage current. This is in spite of the greater thickness of the re-nitrided NO layer. Re-nitrided oxide was expected to have lower barrier height and thus, was expected to have a higher leakage. These results may indicate that the oxidation process has healed the defects in the nitride film which compensates for the barrier lowering effect. It is noted that a conventional furnace may be used for the nitridation process instead of RTP.

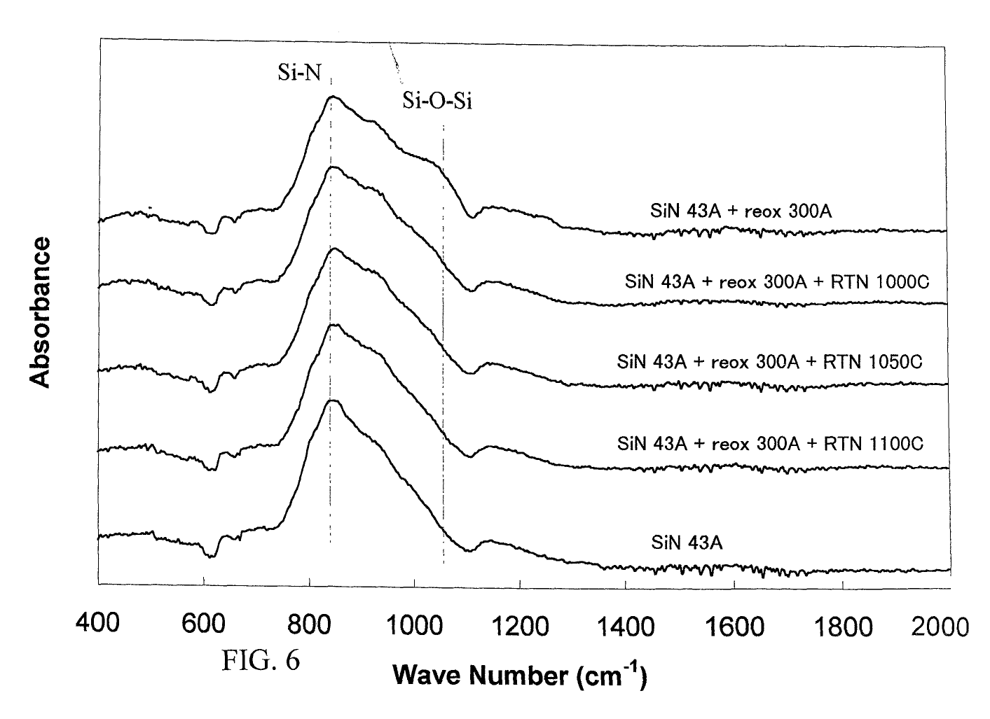

FIG. 6 is a chart illustrating an FTIR (Fourier Transform Infra Red) spectra from 43 Å SiN+300 Å reoxidation, 43 Å SiN+300 Å reoxidation+1000 C RTN, 43 Å SiN+300 Å reoxidation+1050 C RTN, 43 Å SiN+300 Å reoxidation+1100 C RTN and 43 Å SiN. In the case of 43 Å SiN+300 Å reoxidation, a clear spectrum signal associated with Si—O—Si stretching vibration mode is observed at around 1060 c⁻¹. This is attributed to the oxide layer on the SiN film. The intensity of this band decreases with the RTN process depending upon the temperature of the process. That is, the effectiveness of the re-nitridation of the oxide layer is increased depending upon the temperature used. Compared with the 43 Å SiN case, the re-nitrided layer is most likely an oxynitrid film. This is consistent with the electrical data shown above.

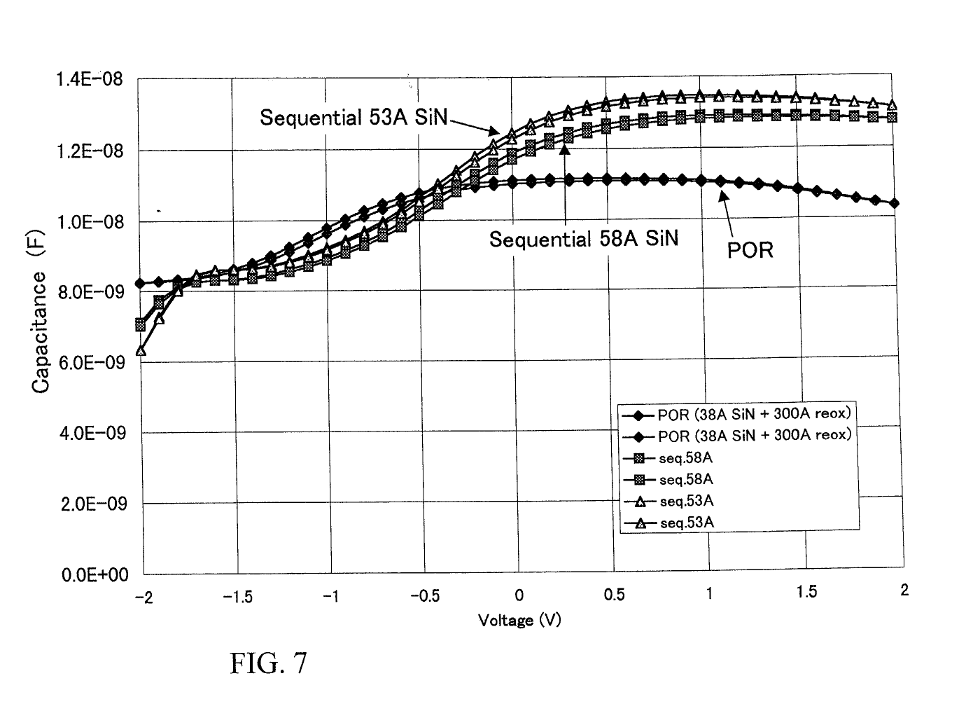

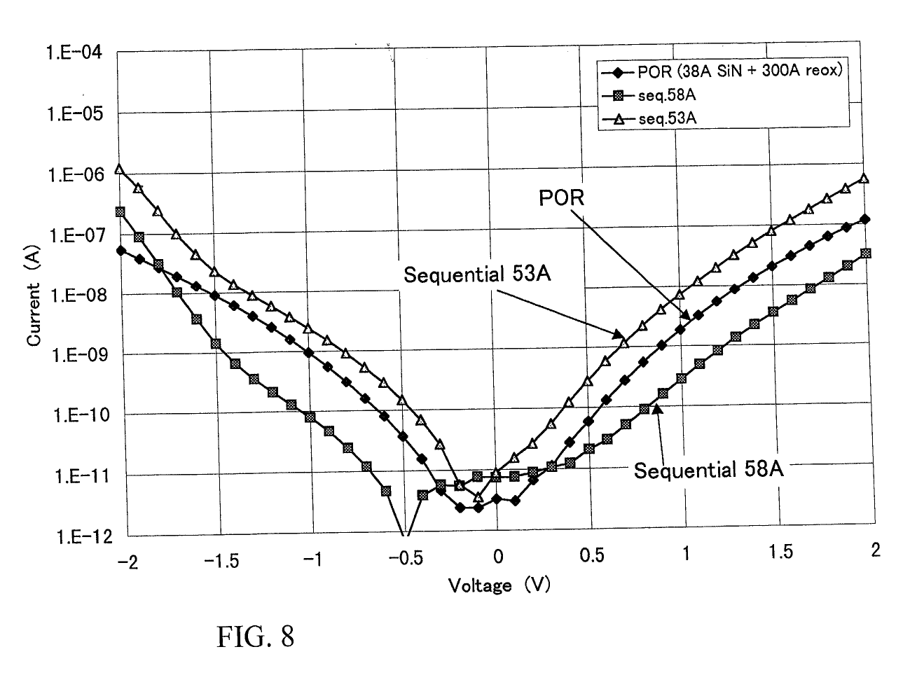

FIGS. 7 and 8 illustrate, respectively, capacitance versus voltage and current versus voltage for a number of 256 K trench array capacitors having dielectrics formed either by conventional NO (POR) methods and by sequential ammonia anneal according to an embodiment of the second process of the invention. In a conventional case, 38 Å SiN deposition and 250 Å EOT on Si oxidation were used. In the “Sequential 53A SiN” and “Sequential 58A SiN” cases, 53 Å and 58 Å thick SiN films were formed with cycled, sequential ammonia annealing at 900-1050 C. at 9 Torr for 30 minutes, repeated four times. For such a process, a fast-thermal-process-type furnace may be used. It was observed that the SiN films formed by the sequential nitridation process have a higher capacitance than those formed by a conventional process (POR). Although the “Sequential 53A SiN” case has a slightly higher leakage current than the POR case, the “Sequential 58A SiN” case has lower current. This data indicates that the cycled, sequential ammonia annealing during SiN deposition provides SiN single composition films with high quality that may be used as capacitor dielectrics.

The embodiments and examples set forth herein were presented in order to best explain the present invention and its practical application and to thereby enable those of ordinary skill in the art to make and use the invention. However, those of ordinary skill in the art will recognize that the foregoing description and examples have been presented for the purposes of illustration and example only. The description as set forth is not intended to be exhaustive or to limit the invention to the precise form disclosed. Many modifications and variations are possible in light of the teachings above without departing from the spirit and scope of the forthcoming claims. For example, it will be clear to those of ordinary skill in the art that the methods of forming a dielectric film with low leakage described herein are readily applicable to a variety of on-chip structures and the invention is not limited to the trench capacitor embodiments shown and described herein.

1. A method of forming a node dielectric for a capacitor, the method comprising:
a. forming a nitride film on a semiconductor surface;
b. oxidizing at least a portion of the nitride film; and
c. nitriding at least a portion of the oxidized nitride film.

2. The method of claim 1, wherein oxidizing at least a portion of the nitride film comprises oxidizing the film by free radical enhanced rapid thermal oxidation.

3. The method of claim 1, wherein nitriding at least a portion of the oxidized nitride film comprises nitriding the film by at least one of rapid thermal nitridation, remote plasma nitridation and decoupled plasma nitridation.

4. The method of claim 1, wherein forming a nitride film on a semiconductor surface comprises applying a first thin layer of nitride, baking the first thin layer, and applying a second thin layer of nitride.

5. The method of claim 4, wherein forming a nitride film on a semiconductor surface further comprises baking the second thin layer and applying a third thin layer of nitride, and baking the third thin layer of nitride and applying a fourth thin layer of nitride.

6. A method of forming a node dielectric for a capacitor, the method comprising:
a. depositing a first thin nitride film on a semiconductor surface;
b. baking the first thin nitride film at an elevated temperature;
c. depositing a second thin nitride film on the first nitride film; and
d. baking the second thin nitride film at an elevated temperature.

7. The method of claim 6, further comprising:
a. depositing a third thin nitride film on the second nitride film;
b. baking the third thin nitride film at an elevated temperature;
c. depositing a fourth thin nitride film on the third nitride film; and
d. baking the fourth thin nitride film at an elevated temperature.

8. The method of claim 6, further comprising oxidizing at least a portion of at least one thin nitride film after a final thin nitride film is deposited.

9. The method of claim 8, wherein oxidizing at least a portion of at least one nitride film comprises oxidizing the film by free radical enhanced rapid thermal oxidation.

10. The method of claim 9, further comprising nitriding at least a portion of the oxidized nitride film.

11. The method of claim 10, wherein nitriding at least a portion of the oxidized nitride film comprises nitriding the film by at least one of rapid thermal nitridation, remote plasma nitridation and decoupled plasma nitridation.

12. The method of claim 6, wherein baking each of the first and second thin nitride films at an elevated temperature comprises soaking each thin film in ammonia at a temperature of between 500 C. and 1150 C.

13. The method of claim 6, wherein depositing each of the first and second thin nitride films comprises depositing a film having a thickness of approximately 5 Å.

14. A method of forming a node dielectric for a capacitor, the method comprising:
a. depositing a first thin nitride film on a semiconductor surface;
b. nitriding at least a portion of the first thin nitride film;
c. depositing a second thin nitride film on the nitrided first nitride film; and
d. nitriding at least a portion of the second thin nitride film.

15. The method of claim 14, further comprising:
a. depositing a third thin nitride film on the nitrided second nitride film;
b. nitriding at least a portion of the third thin nitride film;
c. depositing a fourth thin nitride film on the nitrided third nitride film; and
d. nitriding at least a portion of the fourth thin nitride film.

16. The method of claim 14, further comprising oxidizing at least a portion of at least one thin nitride film after a final thin nitride film is deposited.

17. The method of claim 16, further comprising nitriding at least a portion of the oxidized nitride film.

18. The method of claim 17, wherein nitriding at least a portion of the oxidized nitride film comprises nitriding the film by at least one of rapid thermal nitridation, remote plasma nitridation and decoupled plasma nitridation.

19. The method of claim 14, wherein nitriding at least a portion of each of the first and second thin nitride films comprises nitriding each film by at least one of rapid thermal nitridation, remote plasma nitridation and decoupled plasma nitridation.

20. The method of claim 14, wherein depositing each of the first and second thin nitride films comprises depositing a film having a thickness of approximately 5 Å.
